(19) United States
(12) Patent Application Publication
(10) Pub. No.: US 2010/0110621 A1
(43) Pub. Date: May 6, 2010

(54) RACK WITH VERTICAL MOUNTING PROVIDING ROOM FOR RACK PDU

(75) Inventors: Phillip Richard Dunn, Dublin, OH (US); Michael Rhodes, Larue, OH (US)

Correspondence Address: HARNESS, DICKEY & PIERCE, P.L.C., P.O. BOX 828, BLOOMFIELD HILLS, MI, 48303, US

(73) Assignee: Liebert Corporation, Columbus, OH (US)

(21) Appl. No.: 12/570,204

(22) Filed: Sep. 30, 2009

Related U.S. Application Data
(60) Provisional application No. 61/110,201, filed on Oct. 31, 2008.

(51) Int. Cl. H05K 5/00; A47F 7/00

(52) U.S. Cl. 361/679.01; 211/26

(57) ABSTRACT

An electronic component equipment rack utilizes vertically extending adjustable rails to support electronic components therein. The vertically extending rails are configured to allow a power distribution unit to be attached thereto. The dimensions of the vertically extending rails allow the power distribution unit to be disposed between the attached vertically extending rail and an associated adjacent opposed side of the rack. The vertically extending rails can be Z-shaped with front and rear flanges and a side panel extending therebetween. The power distribution unit can be attached to the rear flange and be adjacent the rear flange and the side panel. The power distribution unit can be flush with the front flange. The rack and the opening between opposing vertically extending rails can conform to the EIA3 10-D standard.

### CROSS-REFERENCE TO RELATED APPLICATIONS

This application claims the benefit of U.S. Provisional Application No. 61/110,201, filed on Oct. 31, 2008. The entire disclosure of the above application is incorporated herein by reference.

### FIELD

The present disclosure relates to a rail for electronic equipment racks, and more particularly, to a rail for use in a rack system for mounting electronic equipment.

### BACKGROUND

This section provides background information related to the present disclosure which is not necessarily prior art.

Electronic equipment is often mounted in racks. A rack may be a cabinet, open or closed. One standardized rack is the nineteen inch rack that is subject to standards issued by various organizations. One such standard is the EIA 310-D standard, a standard promulgated by the Electronic Industries Association. A single rack may be different heights, but typically has a 42 U form. That is, it can hold up to 42 modules having a 1U form (or any combination of 1U, 2U, 3U, etc., that add up to 42). A 1U form has a height of 1.75 inches. The nineteen inch rack has opposed vertical rails on opposed sides of the cabinet, typically two opposed vertical rails at the front of the cabinet and two opposed vertical rails at the rear of the cabinet. The nineteen inches is the width of the front panel of the equipment that is mounted in the rack. The vertical rails have a series of mounting holes therein that run along the length of the vertical rails. When the vertical rails are mounted in the racks, the mounting holes are spaced slightly less than nineteen inches from each other. EIA 310-D specifies that the distance between centerlines of the mounting holes of the opposed vertical racks is 18 5/16 inches. EIA 310-D also specifies that the opening between the opposed vertical rails be at least 17¾ inches. It also specifies the spacing of the mounting holes that run along the length of the vertical rails. The hole spacing for a 1U rack unit includes three holes that alternates at ½ inch, ⅝ inch, ⅝ inch. The start and stop of the “1U” spacing is the middle of the ½ inch spaced holes of adjacent 1U rack units. The opposed vertical rails are typically disposed in both the front and rear of the cabinet. To accommodate the vertical rails and the opening between them, the cabinet is wider than nineteen inches, typically twenty-four inches (600 mm) wide. The equipment may be attached directly to the vertical rails, or may be attached to rails that slide in and out of the cabinet which in turn are attached to the vertical rails.

A common configuration of the vertical rails is an L shape having a flange that extends along an inside wall of the cabinet and a flange that extends inwardly from the inside wall of the cabinet.

### SUMMARY

This section provides a general summary of the disclosure, and is not a comprehensive disclosure with its full scope or all of its features.

An electronic equipment rack according to the present disclosure can include a pair of opposed side walls and front and rear pairs of vertically extending adjustable rails. Each front rail can be adjacent different ones of the opposed side walls and each rear rail can be adjacent different ones of the opposed side walls. A power distribution unit is disposed between a first one of the vertically extending rails and the associated adjacent opposed side wall. The power distribution unit is attached to the first vertically extending rail.

A system of supporting and providing power to electronic components in a cabinet which conforms to EIA 310-D standard according to the present disclosure can include a plurality of adjustable vertically extending rails configured to be retained and supported by upper and lower side rails attached to side walls of the cabinet. Each of the vertically extending rails includes first and second flanges, a side panel, and top and bottom mounting flanges. The first flange can have a plurality of first mounting holes therein extending along its vertical length for attaching electronic equipment thereto. The first mounting holes conform to the EIA 310-D standard. The second flange is spaced apart from and substantially parallel with the first flange. The second flange has a plurality of second mounting holes therein extending vertically along its vertical length. The second mounting holes including a repeating series of hole groupings with each grouping having a rectangular hole vertically flanked on either side with a circular hole. The side panel extends substantially orthogonally between the first and second flanges and is substantially parallel with the side walls of the cabinet when the vertically extending rail is attached thereto. The side panel has a plurality of third mounting holes therein which include holes having a same configuration as the first and second mounting holes along with a plurality of elongated vertically extending slots. The top mounting flange has a paw configured to be received in a T-slot of the upper side rail. The bottom mounting flange has a lip configured to be received in a T-slot of the lower side rail. A vertically extending power distribution unit is attached to the second flange of a first one of the vertically extending rails. The power distribution unit has a transverse dimension parallel with the second flange that is about 1.75 inches. The first and second flanges are dimensioned such that the side panel is transversely spaced apart from a closest side wall of the cabinet greater than about 1.75 inches when attached to the upper and lower side rails of the cabinet. The power distribution unit is located between the side panel of the first vertically extending rail and the closest side wall.

A vertical support rail for an electronic equipment cabinet conforming to EIA 310-D standard according to the present disclosure includes a first flange having a plurality of first mounting holes therein extending along its vertical length for attaching electronic equipment thereto. The first mounting holes conform to the EIA 310-D standard. A second flange is spaced apart from and substantially parallel with the first flange. The second flange has a plurality of second mounting holes therein extending along its vertical length. The second mounting holes include a repeating series of vertically extending hole groupings with each grouping having a rectangular hole vertically flanked on either side with a circular hole. There is a side panel that extends substantially orthogonally between the first and second flanges. The side panel has a plurality of third mounting holes therein. The third mounting holes include holes having a same configuration as the first and second mounting holes along with a plurality of elongated vertically extending slots. There is a top mounting flange having a paw configured to be received in a T-slot of an upper side rail of the cabinet. There is also a bottom mounting flange having a lip configured to be received in a T-slot of a lower side rail of the cabinet. The first and second flanges are dimensioned such that the side panel is transversely spaced apart from a closest side wall of the cabinet greater than about 1.75 inches when attached to the upper and lower side rails of the cabinet. A vertically extending power distribution unit can be attached to the second flange and located between the side panel and the closest side wall.

### DRAWINGS

The drawings described herein are for illustrative purposes only of selected embodiments and not all possible implementations, and are not intended to limit the scope of the present disclosure.

FIG. 1 is a fragmented front perspective view of a rack having vertical mounting rails in accordance with an aspect of the disclosure;

FIG. 2 is an isometric view of a vertical mounting rail of the rack of FIG. 1;

FIG. 3 is a fragmented side perspective view of one of the vertical mounting rails of FIG. 1 having toolless cable management pieces attached thereto;

FIG. 4 is a fragmented plan view of an upper mounting flange of the vertical mounting rail of FIG. 2 attached to a side member of the rack of FIG. 1; and

FIG. 5 is a cross-sectional view along line 5-5 of FIG. 1.

Corresponding reference numerals indicate corresponding parts throughout the several views of the drawings.

### DETAILED DESCRIPTION

Example embodiments will now be described more fully with reference to the accompanying drawings.

With reference to the figures, a nineteen inch EIA rack cabinet 100 has a plurality of vertical mounting rails 102 to which equipment modules or rails supporting equipment modules can be mounted. Each vertical mounting rail 102 has a front flange 104, a rear flange 106, and a side panel 108 extending therebetween. Front flange 104, rear flange 106 and side panel 108 extend longitudinally virtually the entire length of vertical mounting rail 102. In an illustrative embodiment, front and rear flanges 104, 106 and side panel 108 are oriented to provide a Z-shaped EIA vertical mounting rail. That is, vertical mounting rail 102 has a Z-shaped cross-section when viewed from the top or bottom. Front and rear flanges 104, 106 may be parallel to one another while side panel 108 extends therebetween at a right angle (orthogonal) relative to both front and rear flanges 104, 106. Vertical mounting rail 102 includes mounting flanges 110 at the top 110a and bottom 110b which extend outwardly (as oriented with respect to cabinet 100) and include a portion parallel to side plate 108 which abuts against and is affixed to cabinet 100 at a side 111 of cabinet 100, such as to upper and lower side members 112 of cabinet 100.

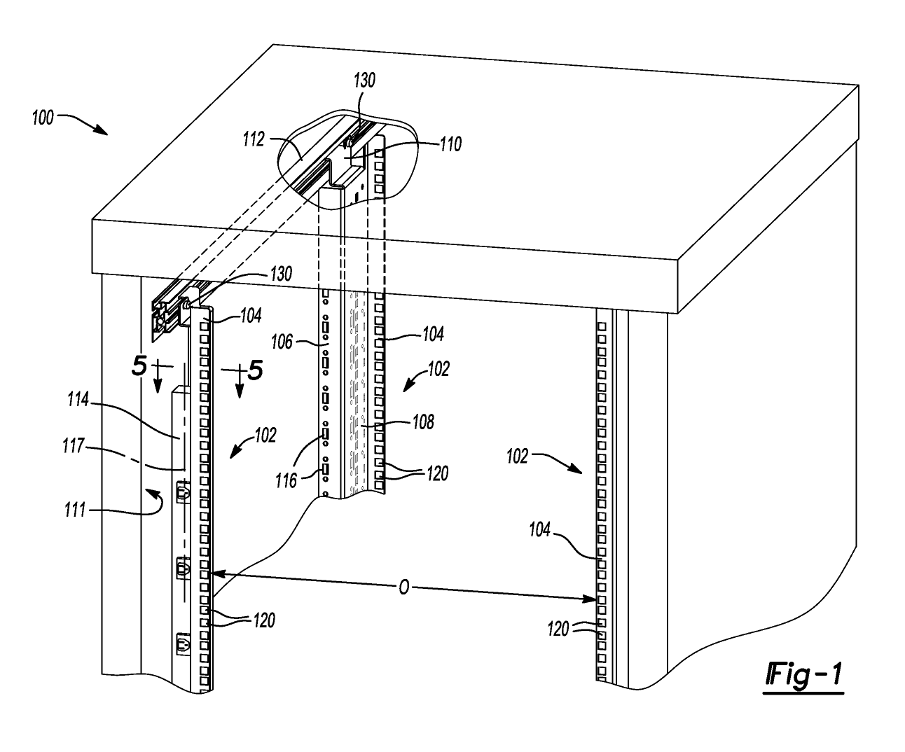

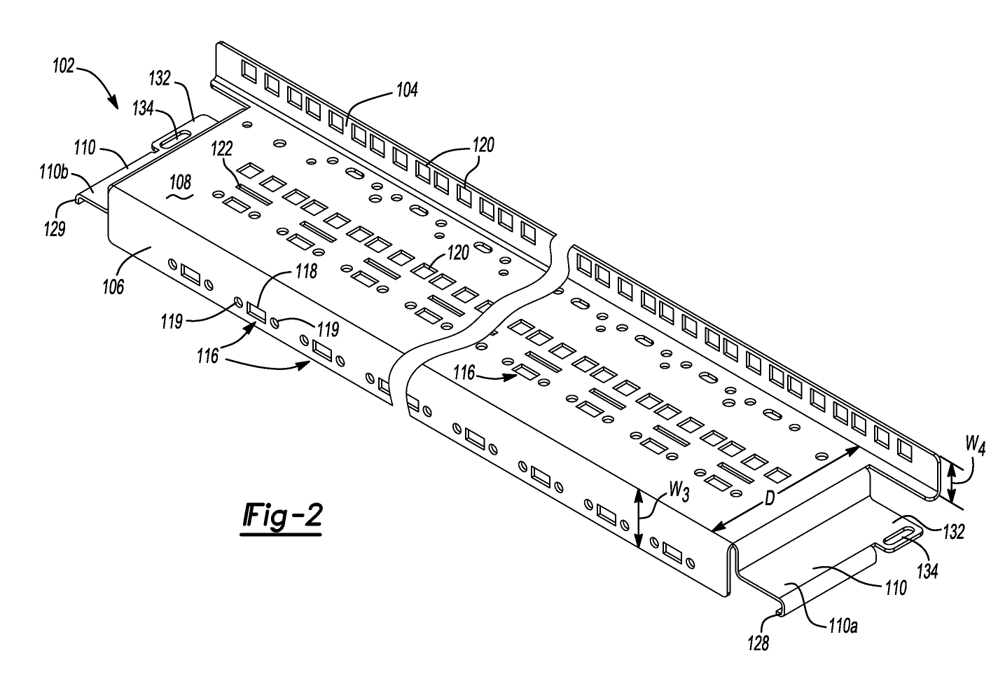

Vertical mounting rail 102 is dimensioned so that when its mounting flanges 110 are attached at a side of cabinet 100, side panel 108 is spaced from the side 111 of cabinet 100 a distance W₁ sufficient to allow a power distribution unit (“PDU”) 114 (FIGS. 1 and 5) that is no more than 1U wide to be disposed between side panel 108 and the side 111 of the cabinet 100. Common PDUs illustratively have a 1U form factor, that is, a width W₂ of 1.75 inches. There are PDUs wider than 1U. Therefore, vertical mounting rail 102 is dimensioned so that when its mounting flanges 110 are attached at a side of cabinet 100, side panel 108 of vertical mounting rail 102 is spaced slightly more than 1.75 inches from the side 111 of the cabinet 100 (i.e., W₁ is slightly more than 1.75 inches, such as 1.8 inches by way of non-limiting example). Side panel 108 of vertical mounting rail 102 illustratively has a depth D approximately equal to a depth of PDU 114. PDU 114 may by way of example and not of limitation have a depth of approximately 3.61 inches. PDU 114 may be substantially flush with front flange 104, such as shown in FIG. 5.

Rear flange 106 has a series of mounting holes 116 extending along its length. Illustratively, mounting holes 116 align with a centerline 117 of PDU 114 when PDU 114 is mounted to vertical mounting rail 102. PDU 114 illustratively includes tabs (not shown) that are received in mounting holes 116 in rear flange 106. Mounting holes 116 may illustratively include a series of hole groupings with each hole grouping including a rectangular hole 118 flanked on either side with a circular hole 119. It should be understood that mounting holes 116 can include other hole groupings, where each grouping has one or more holes. It should also be understood that the mounting holes 116 can have other shapes. In the case of a vertical mounting rail 102 used in a rack conforming to the EIA 310-D standard, rear flange 106 has a width W₃ of approximately 1.06 inches.

Front flange 104 includes mounting holes 120 for the electronic equipment. By way of example and not of limitation, mounting holes 120 conform to the EIA 310-D standard of a grouping of inch, ⅝ inch and ⅝ inch holes for each 1U rack unit.

Front flange 104 is dimensioned so that the requisite opening O (FIG. 1) is provided between opposed vertical mounting rails 102. In the case of the EIA 310-D standard, this opening is a minimum of 17¾ inches and front flange 104 of vertical mounting rail 102 illustratively has a width W₄ of approximately 0.59 inches. In this regard, the width W₄ of front flange 104 is less than the width of the front flange of prior art vertical mounting rails. The reduced width W₄ of front flange 104 facilitates mounting PDU 114 between side panel 108 of vertical mounting rail 102 and the side 111 of cabinet 100 yet still provides the requisite opening O between opposed vertical mounting rails 102 in the front of cabinet 100 and the rear of cabinet 100.

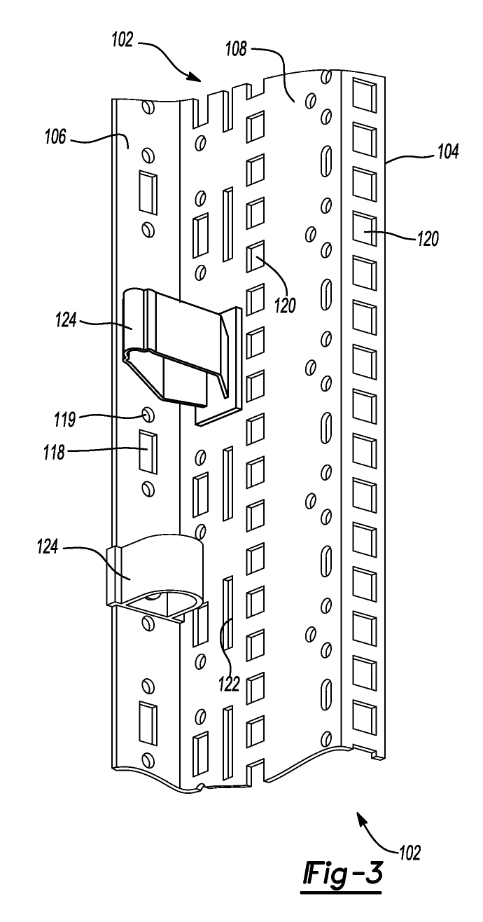

Side panel 108 illustratively includes a plurality of mounting holes, which may include mounting holes that are the same as mounting holes 116 and mounting holes that are the same as mounting holes 120. Side panel 108 may illustratively include mounting slots 122 that receive mounting tabs of cable management pieces 124 (FIG. 3), which may for example be toolless mounting cable management pieces such as those available from Knurr A G of Arnstor, Germany, or Liebert Corporation of Columbus Ohio, which may utilize the Knurr T-slot mounting.

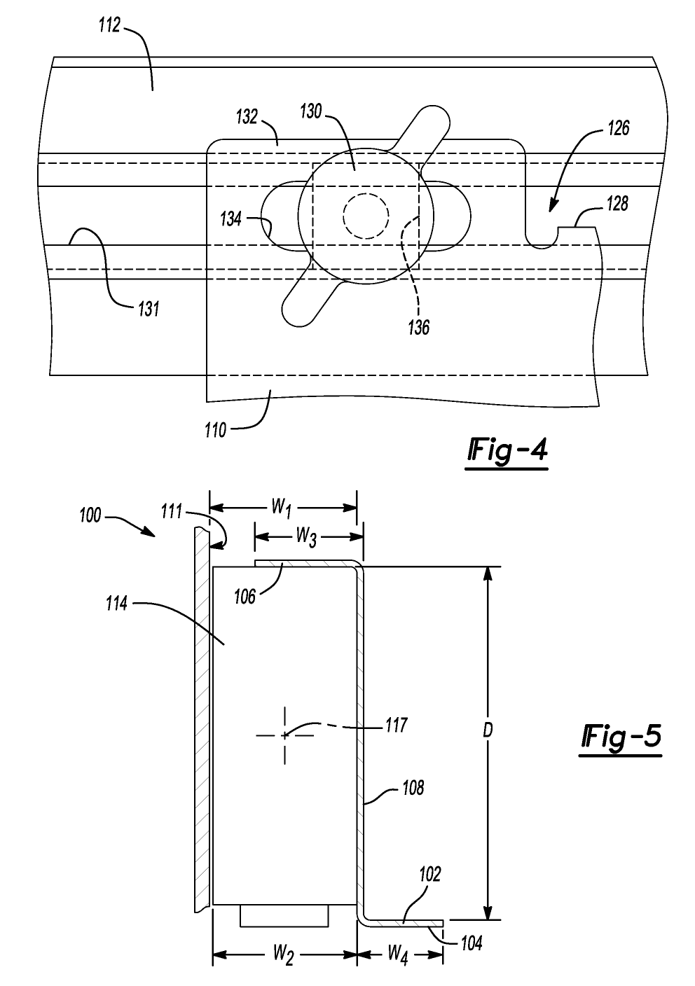

In this regard, mounting flanges 110 may attach to respective side members 112 of cabinet 100 utilizing the Knurr T-slot mounting. Cabinet 100 may include upper and lower side members 112, with two upper side members 112 on respective opposite upper sides 111 of cabinet 100 and two lower side members 112 on respective opposite lower sides 111 of cabinet 100. With reference to FIG. 4, each side member 112 of cabinet 100 may illustratively include a T-slot 126 in which a nut 136, which may be square in shape by way of non-limiting example, is received. The upper mounting flange 110a of each vertical mounting rail 102 includes a “paw” 128 that is received in T-slot 126. Paw 128 may illustratively be a hooked flange that projects outwardly from upper mounting flange 110a so as to fit into T-slot 126 of an upper side member 112 and hook over a portion of upper side member 112 defining a lower edge 131 of T-slot 126. The paws 128 bear the weight of vertical mounting rails 102 when vertical mounting rails 102 are affixed to side members 112, and thus also bear the weight of the equipment mounted to vertical mounting rails 102. Each lower mounting flange 110b may include an outwardly extending flange 129 that is received in a slot, which may be a T-slot 126, in lower side member 112. Each mounting flange 110 also includes a longitudinally extending flange 132 having a slot 134 therein through which fastener 130 is inserted and tightened in the nut 136 in T-slot 126. Engagement of fastener 130 with nut 136 allows vertical rails 102 to be adjusted to and secured in a desired position on side members 112.

The terminology used herein is for the purpose of describing particular example embodiments only and is not intended to be limiting. As used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on”, “engaged to”, “connected to” or “coupled to” another element or layer, it may be directly on, engaged, connected or coupled to the other element or layer, or intervening elements or layers may be present. In contrast, when an element is referred to as being “directly on,” “directly engaged to”, “directly connected to” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath”, “below”, “lower”, “above”, “upper” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The foregoing description of the embodiments has been provided for purposes of illustration and description. It is not intended to be exhaustive or to limit the invention. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the invention, and all such modifications are intended to be included within the scope of the invention.

What is claimed is:

1. An electronic equipment rack comprising:
a pair of opposed side walls;
a front pair of vertically extending adjustable rails, each front rail being adjacent different ones of the opposed side walls;
a rear pair of vertically extending adjustable rails, each rear rail being adjacent different ones of the opposed side walls; and
a power distribution unit disposed between a first one of said vertically extending rails and the associated adjacent opposed side wall, the power distribution unit being attached to the first vertically extending rail.

2. The rack of claim 1, further comprising a pair of horizontally extending side rails each coupled to different ones of the opposed side walls, each one of the pair of front vertically extending rails adjustably attached to different ones of the side rails, and each one of the pair of rear vertically extending rails adjustably attached to different ones of the side rails, the pair of side rails supporting the vertically extending rails and electronic equipment coupled thereto.

3. The rack of claim 2, wherein each of the vertically extending rails is generally Z-shaped in transverse cross-section and includes a front flange, a rear flange substantially parallel with the front flange, and a side panel extending substantially orthogonally between the front flange and the rear flange.

4. The rack of claim 3, wherein the front flange includes a plurality of first mounting holes therein for attaching electronic equipment thereto, the first mounting holes conforming to the EIA 310-D standard.

5. The rack of claim 4, wherein the rear flange includes a plurality of second mounting holes therein extending along its vertical length, the second mounting holes being generally aligned with a vertical centerline of the power distribution unit.

6. The rack of claim 5, wherein the second mounting holes include a repeating series of hole groupings with each grouping having a rectangular hole vertically flanked on either side with a circular hole.

7. The rack of claim 5, wherein the side panel includes a plurality of third mounting holes therein, the third mounting holes including holes having a same configuration as the first and second mounting holes along with a plurality of elongated vertically extending slots, and further comprising at least one cable management member toollessly attachable to the second flange and side panel using the respective second and third mounting holes.

8. The rack of claim 4, wherein the side panel of each of the vertically extending rails is substantially parallel with the opposed side walls, the side panel is transversely spaced apart from a closest adjacent one of the opposed side walls a first distance, and the power distribution unit has a transverse width of a second distance slightly less than the first distance.

9. The rack of claim 8, wherein the second distance is about 1.75 inches.

10. The rack of claim 8, wherein the front pair of vertically extending rails is transversely spaced apart from one another such that an opening between the front flanges is at least about 17.75 inches and conforms to EIA 310-D standard.

11. The rack of claim 8, wherein a face of the power distribution unit is substantially flush with the front flange of the first vertically extending rail.

12. A system supporting and providing power to electronic components in a cabinet conforming to EIA 310-D standard, the system comprising:
a plurality of adjustable vertically extending rails configured to be retained and supported by upper and lower side rails attached to side walls of the cabinet, each of the vertically extending rails including:
a first flange having a plurality of first mounting holes therein extending along its vertical length for attaching electronic equipment thereto, the first mounting holes conforming to the EIA 310-D standard;
a second flange spaced apart from and being substantially parallel with the first flange, the second flange having a plurality of second mounting holes therein extending vertically along its vertical length, the second mounting holes including a repeating series of hole groupings with each grouping having a rectangular hole vertically flanked on either side with a circular hole;
a side panel extending substantially orthogonally between the first and second flanges and being substantially parallel with the side walls of the cabinet, the side panel having a plurality of third mounting holes therein, the third mounting holes including holes having a same configuration as the first and second mounting holes along with a plurality of elongated vertically extending slots;
a top mounting flange having a paw configured to be received in a T-slot of the upper side rail;
a bottom mounting flange having a lip configured to be received in a T-slot of the lower side rail; and
a vertically extending power distribution unit attached to the second flange of a first one of the vertically extending rails, the power distribution unit having a transverse dimension parallel with the second flange that is about 1.75 inches,
wherein the first and second flanges are dimensioned such that the side panel is transversely spaced apart from a closest side wall of the cabinet greater than about 1.75 inches when attached to the upper and lower side rails of the cabinet, and the power distribution unit is located between the side panel of the first vertically extending rail and the closest side wall.

13. The system of claim 12, wherein the power distribution unit is substantially flush with the first flange of the first vertically extending rail.

14. The system of claim 13, wherein a vertical centerline of the power distribution unit is aligned with the second mounting holes in the second flange of the first vertically extending rail.

15. The system of claim 14, wherein the first and second flanges are dimensioned such that the first flanges of each transversely opposed pair of vertically extending rails when attached to transversely opposed side walls of the cabinet are spaced apart with an opening therebetween having a transverse dimension of at least about 17.75 inches in conformance with the EIA 310-D standard.

16. The system of claim 15, wherein the cabinet is a 24 inch or 600 mm wide cabinet.

17. A vertical support rail for an electronic equipment cabinet conforming to EIA 310-D standard, the rail comprising:
a first flange having a plurality of first mounting holes therein extending along its vertical length for attaching electronic equipment thereto, the first mounting holes conforming to the EIA 310-D standard;
a second flange spaced apart from and being substantially parallel with the first flange, the second flange having a plurality of second mounting holes therein extending along its vertical length, the second mounting holes including a repeating series of vertically extending hole groupings with each grouping having a rectangular hole vertically flanked on either side with a circular hole;
a side panel extending substantially orthogonally between the first and second flanges, the side panel having a plurality of third mounting holes therein, the third mounting holes including holes having a same configuration as the first and second mounting holes along with a plurality of elongated vertically extending slots;
a top mounting flange having a paw configured to be received in a T-slot of an upper side rail of the cabinet; and
a bottom mounting flange having a lip configured to be received in a T-slot of a lower side rail of the cabinet,
wherein the first and second flanges are dimensioned such that the side panel is transversely spaced apart from a closest side wall of the cabinet greater than about 1.75 inches when attached to the upper and lower side rails of the cabinet, and a vertically extending power distribution unit can be attached to the second flange and located between the side panel and the closest side wall.

18. The rail of claim 17, wherein the wherein the first and second flanges are dimensioned such that the side panel is transversely spaced apart from a closest side wall of the cabinet slightly greater than about 1.75 inches when attached to the upper and lower side rails of the cabinet and the power distribution unit has a transverse dimension parallel with the second flange that is about 1.75 inches.

19. The rail of claim 17, wherein the side panel is dimensioned such that the power distribution unit is substantially flush with the first flange when attached to the second flange.

20. The rail of claim 19, wherein the second flange is dimensioned such that a vertical centerline of the power distribution unit is aligned with the second mounting holes when attached to the second flange.
